(19) United States
(12) Patent Application Publication
(10) Pub. No.: US 2022/0246669 A1
(43) Pub. Date: Aug. 4, 2022

(54) ONE-PIECE DEVICE FOR DETECTING PARTICLES WITH SEMICONDUCTOR MATERIAL

(71) Applicants: Universite d'Aix Marseille, Marseille Cedex 07 (FR); Centre National de la Recherche Scientifique, Paris Cedex 16 (FR)

(72) Inventor: Wilfried VERVISCH, Lancon-Provence (FR)

(73) Assignees: Universite d'Aix Marseille, Marseille Cedex 07 (FR); Centre National de la Recherche Scientifique, Paris Cedex 16 (FR)

(21) Appl. No.: 17/629,671

(22) PCT Filed: Jul. 22, 2020
(86) PCT No.: PCT/FR2020/051335

§ 371 Date: Jan. 24, 2022

(30) Foreign Application Priority Data
Jul. 26, 2019 (FR) 1908506

(51) Int. Cl. H01L 27/146

(52) U.S. Cl. CPC H01L 27/14659

(57) ABSTRACT

A one-piece device for detecting particles with semiconductor material includes a substrate layer and at least one additional layer disposed on a first face of the substrate layer so as to form at least one first detector comprising a first space charge zone through which a beam of particles passes and first collector means for charge carriers produced by this passage. It further includes at least one other additional layer disposed on a second face of the same substrate layer, opposite the first face, so as to form at least one second detector comprising a second space charge zone through which the beam of particles also passes and second collector means for charge carriers produced by this passage.

The present invention relates to a one-piece particle detection device with semiconductor material.

The notion of “particles” must be taken here in a broad sense and includes elementary or composite particles of matter such as hadrons (neutrons, protons, . . . ) or leptons, as well as electromagnetic particles (in accordance with the principle of wave-corpuscle duality) i.e. photons such as ultraviolet rays, infrared rays, X-rays, gamma rays or others. In general, it is any type of particle that can produce charge carriers in an electronic space charge zone formed in a semiconductor material, these charge carriers being then recovered by collectors of a detector. These collectors are in practice electrodes located on both sides of the semiconductor.

This type of detector is mainly used for detection and measurement of particles emanating from a beam of energetic particles, in particular high-energy particles, emanating from a source and aimed at a target, the detection device being then placed between the two to be passed through by the incident beam along a main axis. The industrial applications are multiple, not only in the medical field, for example in radiotherapy, proton therapy or medical imaging, but also in the nuclear, military, surveillance/security or other fields.

Such a detection device generally makes it possible to read, supervise, monitor and even control the beam source in order to precisely control the dose emitted and to check the energy of the particles. Advantageously, it has particle transparency properties to minimize any influence of the measurement on the incident beam, i.e. it has a high transmission coefficient of the beam passing through it, and then allows the reading of this beam and, via a computer, the measurement of the ionizing radiation fluxes emitted by the source in order to readjust the dose and/or the energy delivered and to check the homogeneity of the beam. In radiotherapy, for example, this significantly reduces the risk of overdosing. In medical imaging, it also allows to obtain a significantly more stable reading of the pixels leading to an improvement of the quality of the images during their processing.

Transparency is a very important property because it is essential not to alter the beam for reasons of energy conservation and cost, as the energy consumption of irradiation can reach several kWh or even MWh in radiotherapy, but also for reasons of robustness of the component that reads the passing beam, as energy deposits that are sometimes substantial can alter it during the passage of the beam and reduce its lifetime. It is also important for questions of limiting the amount of heat produced and avoiding the need for a cooling system.

For this reason, the invention applies more particularly to a one-piece semiconductor material particle detection device comprising:
a substrate layer,
at least one additional layer of semiconductor material and/or of at least one conductive material disposed on a first face of the substrate layer so as to form a first detector comprising:
   a first electronic space charge zone through which a first main axis of the detection device to be followed by a particle beam passes, and
   first collector means for collecting charge carriers produced by the particle beam passing through the first space charge zone.

Such a device is for example disclosed in the patent document DE 42 07 431 A1.

In addition to the thermodynamic and even mechanical advantages of certain semiconductor materials, it is essentially the electronic operating parameters that have shown the real interest of this type of detection device compared to conventional ionization chamber or scintillator technologies. The detection is faster and more transparent. For example, response times of the order of nanoseconds are obtained compared to microseconds for ionization chamber detectors. Absolute transparency, defined as the ratio of the integral of the energy of each particle collected after passing through the detector to the total energy of the incident beam, greater than 98% can furthermore be achieved for a 300 μm SiC semiconductor material detection device and for a particle beam at 6 MeV.

To improve the transparency of the detection device, it is possible to play with the thickness of the semiconductor material up to a certain point. A trick is even proposed in patent document WO 2017/198630 A1, consisting of providing a hole in the semiconductor material opposite the space charge zone thus limiting the thickness passed through by the incident beam.

However, a trend towards increased safety of particle-emitting devices increasingly requires redundancy in beam analysis by simultaneous dual detection using two independent detectors. This trend is due in particular to medical applications wherein an overdose can be dangerous. It is all the more sensitive as certain therapeutic advances, notably in oncology, show the interest of treating quickly and strongly, i.e. emitting short but high energy and high precision pulsed beams. This is also valid in other fields than oncology and more generally than medicine. In this case, it is important to perfectly control the emission dosage, because any wrong dosage can have serious consequences, so that double detection is increasingly becoming a requirement defined by the new standards or certifications.

The natural solution to this new requirement is to place two independent detection devices on two different sensors in the path of the incident beam. However, this solution is detrimental to the size, cost and especially the transparency of the whole system.

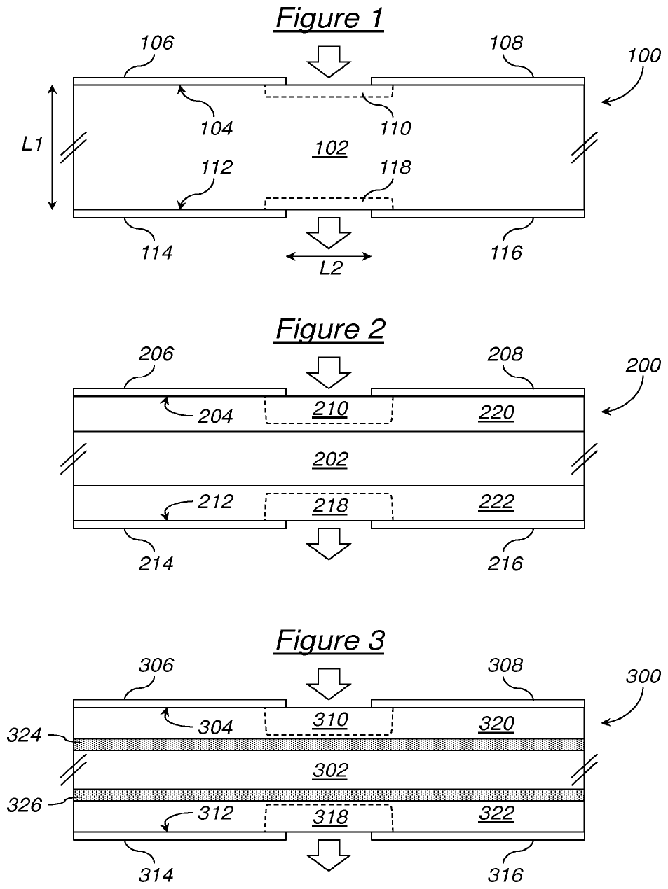

From patent document US 2008/0099871 A1 a one-piece device for detecting particles made of semiconductor material is known, which can comprise an array of detectors, but the latter are not independent. Indeed, what is described for example in paragraphs [0038]-[0044] of this document US 2008/0099871 A1 is a single detector with two PN junctions, located on the front and rear faces of a semiconductor material but electrically connected to each other ([0044]). Similarly, patent document U.S. Pat. No. 5,336,890 relates to a one-piece semiconductor material particle detection device comprising two junctions with associated space charge regions, but the respective collector means are not electrically insulated to ensure the independence of two detectors. FIG. 1 of this document U.S. Pat. No. 5,336,890 illustrates only one detector.

It may thus be desirable to provide a semiconductor material particle detection device that allows to overcome at least some of the abovementioned problems and constraints.

It is therefore proposed a one-piece semiconductor material particle detection device comprising:
a substrate layer,
at least one additional layer of semiconductor material and/or of at least one conductive material disposed on a first face of the substrate layer so as to form a first detector comprising:
   a first electronic space charge zone through which a first main axis of the detection device to be followed by a particle beam passes, and
   first collector means for collecting charge carriers produced by the particle beam passing through the first space charge zone,
      further comprising at least one other additional layer of the semiconductor material and/or said at least one conductive material disposed on a second face of the same substrate layer, opposite to the first face, so as to form a second detector comprising:
a second electronic space charge zone, through which a second main axis of the detection device also intended to be followed by the particle beam passes, and
second collector means for collecting charge carriers produced by the particle beam passing through the second space charge zone.

It should be noted that the substrate layer is formed in the semiconductor material. Said at least one additional layer is formed in the semiconductor material and/or in said at least one conductive material disposed on a first face of the substrate layer. Finally, said first and second axes, which may or may not be referred to as principal axes, are necessarily parallel in order to be followed by the same particle beam.

It should also be noted that any “additional layer” or “other additional layer” defined as formed in the same semiconductor material as the substrate layer is distinguished therefrom by different doping and is presented as such by convention in this patent application. Thus, the substrate layer within the meaning of the present invention does not necessarily extend throughout the semiconductor material, and any “additional layer” or “other additional layer” is not a region thereof, even if defined as formed in the same semiconductor material. This convention differs from that chosen in the aforementioned US 2008/0099871 A1 and does not detract from the consistency of the present patent application.

Advantageously, said at least one other additional layer is formed in the semiconductor material and/or in said at least one conductive material so that said at least one second detector is independent of the first one while being formed from that same substrate layer.

Advantageously too, the second collector means are electrically insulated from the first collector means to ensure the independence of the first and second detectors.

Thus, two independent detectors are formed in the same one-piece device from the same common substrate, on either face of the latter, to allow the increasingly required redundant double detection. This improves the size, cost and transparency of the dual detection by saving a substrate thickness compared to the abovementioned solution. This also avoids the risk of reduced lifetime that conventional sensors currently suffer.

Optionally, a one-piece particle detection device according to the invention may comprise:
a first additional layer of said at least one conductive material, arranged directly on the first face of the substrate layer or indirectly via an additional layer of the semiconductor material epitaxially formed from the substrate layer, so as to form an anode and a cathode of a first Schottky diode, and
a second additional layer of said at least one conductive material, arranged directly on the second face of the substrate layer or indirectly via an additional layer of the semiconductor material epitaxially formed from the substrate layer, so as to form an anode and a cathode of a second Schottky diode.

In other equivalent words:
said at least one additional layer comprises:
   a first additional layer formed in said at least one conductive material, disposed directly on the first face of the substrate layer, or
   a first additional layer formed in the semiconductor material by epitaxy from the substrate layer and the first additional layer formed in the at least one conductive material disposed indirectly on the first face of the substrate layer via this first additional layer formed in the semiconductor material,
so as to form an anode and a cathode of a first Schottky diode, and
said at least one other additional layer comprises:
   a second additional layer formed in said at least one conductive material, disposed directly on the second face of the substrate layer, or
   a second additional layer formed in the semiconductor material by epitaxy from the substrate layer and the second additional layer formed in the at least one conductive material disposed indirectly on the second face of the substrate layer via this second additional layer formed in the semiconductor material,
so as to form an anode and a cathode of a second Schottky diode.

Also optionally, a one-piece particle detection device according to the invention may also comprise:
a first additional layer of said at least one conductive material of which at least one conductor is in contact with at least one additional layer portion of said at least one semiconductor material formed with a reverse doping to that of the substrate layer so as to form a first PIN diode, and
a second additional layer of said at least one conductive material of which at least one conductor is in contact with at least one additional layer portion of said at least one semiconductor material formed with a reverse doping to that of the substrate layer so as to form a second PIN diode.

In other equivalent words:
said at least one additional layer comprises at least one first additional layer portion formed in the semiconductor material with a reverse doping to that of the substrate layer and a first additional layer formed in said at least one conductive material, at least one conductor of which is in contact with said at least one first additional layer portion formed in the semiconductor material, so as to form a first PIN diode; and
said at least one other additional layer comprises at least one second additional layer portion formed in the semiconductor material with a reverse doping to that of the substrate layer and a second additional layer formed in said at least one conductive material of which at least one conductor is in contact with said at least one second additional layer portion formed in the semiconductor material, so as to form a second PIN diode.

Also optionally, a one-piece particle detection device according to the invention may comprise two buffer layers respectively epitaxially formed from the first and second faces of the substrate layer.

Also optionally, a one-piece particle detection device according to the invention may also comprise two holes hollowed out in the semiconductor material on either face of the substrate layer around the first and second main axes that are intended to be followed by the particle beam respectively.

Also optionally, the substrate layer is n++ doped.

Also optionally, a plurality of first detectors and a plurality of second detectors are formed in the one-piece device.

Also optionally, said at least one second detector is formed to have a right angle angular offset from said at least one first detector along the first and second principal axes to be followed by the particle beam.

In other equivalent words, said at least one second detector is formed to have diodes angularly offset at right angles to corresponding diodes of said at least one first detector about the common direction of the first and second parallel axes to be followed by the particle beam.

Also optionally, the substrate layer common to the detectors is formed in the semiconductor material.

Also optionally, the first principal axis and the second principal axis are coincident.

The invention will be better understood with the aid of the following description, which is given only by way of example and is made with reference to the attached drawings wherein:

FIG. 1 diagrammatically shows a cross-section of the general structure of a one-piece particle detection device, according to a first embodiment of the invention,

FIG. 2 diagrammatically shows a cross-section of the general structure of a one-piece particle detection device, according to a second embodiment of the invention,

FIG. 3 diagrammatically shows a cross-section of the general structure of a one-piece particle detection device, according to a third embodiment of the invention,

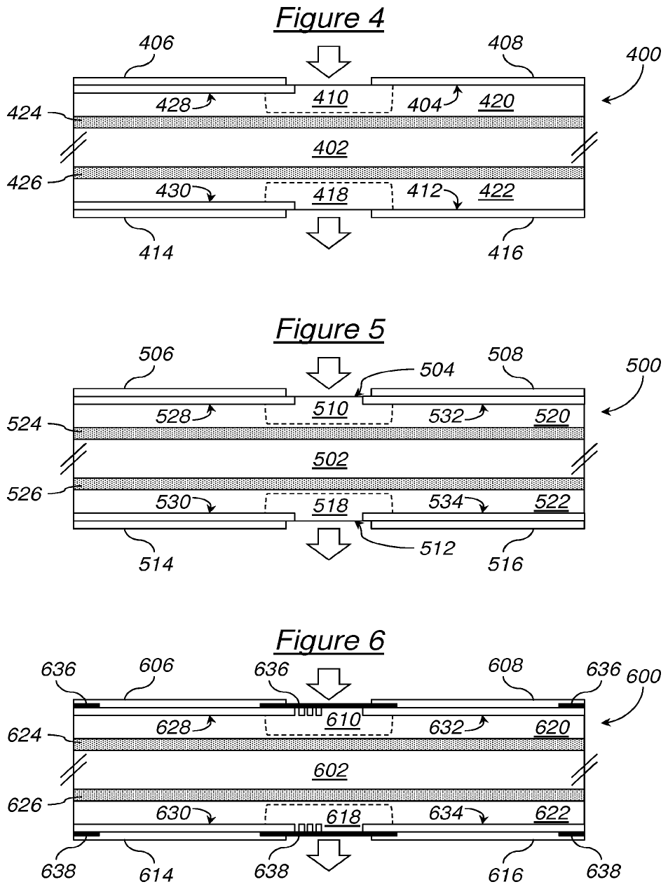

FIG. 4 diagrammatically shows a cross-section of the general structure of a one-piece particle detection device, according to a fourth embodiment of the invention,

FIG. 5 diagrammatically shows a cross-section of the general structure of a one-piece particle detection device, according to a fifth embodiment of the invention,

FIG. 6 diagrammatically shows a cross-section of the general structure of a one-piece particle detection device, according to a sixth embodiment of the invention,

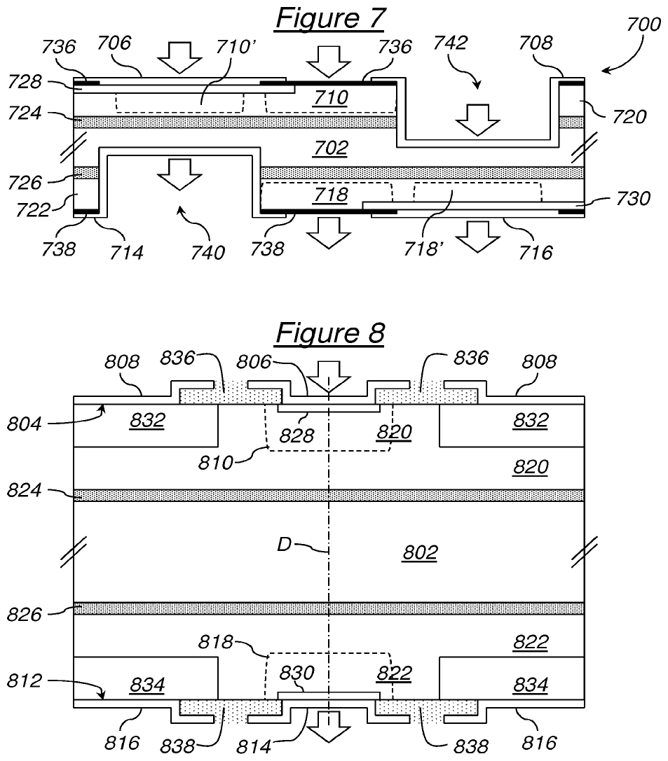

FIG. 7 diagrammatically shows a cross-section of the general structure of a one-piece particle detection device, according to a seventh embodiment of the invention, and

FIG. 8 shows a more detailed cross-sectional view of the structure of a one-piece particle detection device, according to an eighth embodiment of the invention.

The one-piece particle detection device 100 shown schematically in cross-section in FIG. 1 includes a substrate layer 102 the thickness of which is L1, for example 300 μm. It is advantageously made of a semiconductor material, preferably a semiconductor with a large energy band gap such as silicon carbide SiC, diamond or gallium nitride GaN. It is for example n++ doped, but could alternatively be p++ doped.

The device 100 further includes an additional top layer of metallic conductive material disposed directly on a first top face 104 of the substrate layer 102. This additional top layer is made of two disjoint metallic conductors 106 and 108, i.e., electrically insulated from each other, one of which, for example the one with reference 106, performs an anode function and the other of which, for example the one with reference 108, performs a cathode function.

A first Schottky diode forming a first detector is thus formed by forming a first space charge zone 110 in the substrate 102 under its first top surface 104 between the two conductors 106 and 108. This first space charge zone 110 is passed through by a main axis of the detection device 100 intended to be followed by a particle beam, as illustrated in FIG. 1 by the two downward arrows. The anode 106 and the cathode 108, thus forming respectively a Schottky contact and an ohmic contact of the first Schottky diode, constitute first collector means for collecting charge carriers produced by the particle beam passing through the first space charge zone 110.

The device 100 further includes another additional bottom layer of metallic conductive material disposed directly on a second bottom surface 112 of the substrate layer 102. This other additional bottom layer is made of two disjoint metallic conductors 114 and 116, one of which, for example the one with reference 114, performs an anode function and the other of which, for example the one with reference 116, performs a cathode function.

A second Schottky diode forming a second detector is thus formed by forming a second space charge zone 118 in the substrate 102 under its second face 112 between the two conductors 114 and 116. By symmetry of the device 100, this second space charge zone 118 is passed through by the same principal axis followed by the particle beam as the first space charge zone 110. The anode 114 and the cathode 116, thus forming respectively a Schottky contact and an ohmic contact of the second Schottky diode, constitute second collector means for collecting charge carriers produced by the particle beam passing through the second space charge zone 118.

It should be noted that in order for the two space charge zones to form correctly on either face of the substrate 102, the distance L2 between the two collectors of each Schottky diode must be smaller than L1.

It is also worth noting the extreme simplicity of this one-piece Schottky diode detection device 100. While allowing a dual detection by two independent detectors as required more and more often, it makes it possible to preserve very good properties of transparency to the particles, of compactness and of manufacturing costs.

It should also be noted that in the embodiment of FIG. 1, the substrate layer 102 extends throughout the semiconductor material.

The one-piece particle detection device 200 shown schematically in cross-section in FIG. 2 differs from the previous one in the following features:
it has an additional top layer 220 made of semiconductor material between its substrate layer 202 and its top layer of metallic conductive material consisting of two disjoint metallic conductors 206 and 208 forming respectively the anode and the cathode of a first Schottky diode with space charge zone 210, and
it has an additional bottom layer 222 of semiconductor material between its substrate layer 202 and its bottom layer of metallic conductive material consisting of two disjoint metallic conductors 214 and 216 forming respectively the anode and the cathode of a second Schottky diode with space charge zone 218.

The substrate 202 is for example, like the substrate 102, n++ doped. The additional top layer 220 is, for example, n− doped and epitaxially formed above the substrate layer 202 in the same semiconductor material, with its free upper face 204 contacting the collectors 206 and 208. Similarly, the additional bottom layer 222 is, for example, n− doped and epitaxially formed below the substrate layer 202 in the same semiconductor material, with its free lower face 212 contacting the collectors 214 and 216.

The interest of this embodiment compared to the previous one is to extend the space charge zones 210 and 218 in the thickness of the semiconductor material without, however, making the charges disappear in the substrate 202 at the expense of the cathodes 208 and 216, for example. A compromise must be found between the n-doping of the layers 220 and 222, the thickness of this n− doping and the distance between the electrodes 206 and 208 or 214 and 216. This compromise is within the reach of the skilled person.

It should be noted that alternatively the substrate layer 202 could be p++ doped, the additional top layer 220 p− doped and the additional bottom layer 222 p− doped also.

It should also be noted that in the embodiment shown in FIG. 2, the substrate layer 202 does not extend throughout the semiconductor material and in particular does not include the doped layers 220 and 222 which are not regions thereof. The same will be true in the other embodiments that follow, where the substrate layer does not extend throughout the semiconductor material and does not include the “additional layers”, “additional layer portions”, “other additional layers”, or “other additional layer portions” that will eventually be defined there.

The one-piece particle detection device 300 shown schematically in cross-section in FIG. 3 differs from the previous one in the following features:
it has a top buffer layer 324 of semiconductor material between its substrate layer 302 and its additional top layer 320 of semiconductor material, and
it has a bottom buffer layer 326 of semiconductor material between its substrate layer 302 and its additional bottom layer 322 of semiconductor material.

Like the previous one, it comprises a top layer of metallic conductive material, directly in contact with the free upper face 304 of the additional top layer 320 made of semiconductor material, constituted by two disjointed metallic conductors 306 and 308 forming respectively the anode and the cathode of a first Schottky diode with space charge zone 310, as well as a bottom layer of metallic conductive material, directly in contact with the free lower face 312 of the additional bottom layer 322 of semiconductor material, consisting of two disjointed metallic conductors 314 and 316 forming respectively the anode and the cathode of a second Schottky diode with a space charge zone 318.

The substrate 302 is for example, like the substrate 202, n++ doped. The top buffer layer 324 is, for example, n+ doped and epitaxially formed over the substrate layer 302 in the same semiconductor material. The additional top layer 320 is, for example, like the additional top layer 220, n− doped and formed by epitaxy over the top buffer layer 324 in the same semiconductor material. Similarly, the bottom buffer layer 326 is, for example, n+ doped and epitaxially formed below the substrate layer 302 in the same semiconductor material. The additional bottom layer 322 is, for example, n-doped and epitaxially formed below the bottom buffer layer 326 in the same semiconductor material.

The advantage of this embodiment over the previous one is to avoid the upwelling of impurities from the n++ doped substrate 302 to the additional top and bottom layers 320 and 322 of semiconductor material during the epitaxy process. The intermediate n+ doping of the two buffer layers 324 and 326 allows this. It should be noted that although this is a known manufacturing method in the semiconductor field for the manufacture of power devices, it is not the case for the manufacture of detection devices.

It should also be noted that alternatively the substrate layer 302 could be p++ doped, the additional top layer 320 p− doped, the additional bottom layer 322 also p-doped and the two buffer layers 324, 326 p+ doped.

It should further be noted that in the embodiments of FIGS. 1, 2 and 3, the Schottky diodes are formed by arranging the conductive layers directly on both faces of the substrate layer, or indirectly via additional layers of semiconductor material epitaxially formed from the substrate layer.

The one-piece particle detection device 400 shown schematically in cross-section in FIG. 4 comprises, like the previous one:
a substrate layer 402 of n++ doped semiconductor material,
a top buffer layer 424 of n+ doped semiconductor material epitaxially formed over the substrate layer 402,
an additional top layer 420 of n− doped semiconductor material epitaxially formed over the top buffer layer 424,
an additional top layer of metallic conductive material, in contact with the free upper face 404 of the additional top layer 420 of semiconductor material, consisting of two disjoint metallic conductors 406 and 408 forming respectively the anode and the cathode of a first diode with space charge zone 410,
a bottom buffer layer 426 of n+ doped semiconductor material epitaxially formed beneath the substrate layer 402,
an additional bottom layer 422 of n− doped semiconductor material epitaxially formed below the bottom buffer layer 426,
an additional bottom layer of metallic conductive material, directly, in contact with the free lower face 412 of the additional bottom layer 422 of semiconductor material, consisting of two disjoint metallic conductors 414 and 416 forming respectively the anode and the cathode of a first diode with space charge zone 418.

The one-piece particle detection device 400 shown schematically in cross-section in FIG. 4 differs, however, from the previous one in the following features:
it has locally an additional top layer portion 428, formed in the semiconductor material by epitaxy with a p+ doping and interposed between the additional top layer 420 of n− doped semiconductor material and the anode 406 so that the latter is not in direct contact with the n− doped semiconductor material, and
it has locally an additional bottom layer portion 430, formed in the semiconductor material by epitaxy with a p+ doping and interposed between the additional bottom layer 422 of n− doped semiconductor material and the anode 414 so that the latter is not in direct contact with the n− doped semiconductor material.

As a result, the Schottky contacts mentioned above are replaced by ohmic contacts, so that the first diode forming the first detector and the second diode forming the second detector become p-doped PIN diodes (generally noted as PI diodes).

It should be noted that alternatively the substrate layer 402 could be p++ doped, the additional top layer 420 p− doped, the additional bottom layer 422 also p− doped, the two buffer layers 424, 426 p+ doped, and the two additional layer portions n+ doped. This would result in two detectors formed by two n-doped PIN diodes (generally noted as NI diodes).

The one-piece particle detection device 500 shown schematically in cross-section in FIG. 5 comprises elements 502 to 530 respectively identical to elements 402 to 430 of the previous one.

However, it differs from the previous one in that:
it has locally another additional top layer portion 532, formed in the semiconductor material by epitaxy with n++ doping and interposed between the additional top layer 520 of n− doped semiconductor material and the cathode 508 so that the latter is not in direct contact with the n-doped semiconductor material, and
it has locally another additional bottom layer portion 534, formed in the semiconductor material by epitaxy with n++ doping and interposed between the additional bottom layer 522 of n− doped semiconductor material and the cathode 516 so that the latter is not in direct contact with the n− doped semiconductor material.

As a result, the first diode forming the first detector and the second diode forming the second detector become p- and n-doped PIN diodes (generally noted as PIN diodes). This allows a better collecting of charge carriers.

It should be noted that alternatively the substrate layer 502 could be p++ doped, the additional top layer 520 p− doped, the additional bottom layer 522 also p− doped, the two buffer layers 524, 526 p+ doped, the two additional layer portions 528, 530 n+ doped, and the two other additional layer portions 532, 534 p++ doped. This would result in two detectors formed by two n- and p-doped PIN diodes (generally noted as NIP diodes).

The one-piece particle detection device 600 shown schematically in cross-section in FIG. 6 comprises elements 602 to 634 respectively identical to the elements 502 to 534 of the previous one.

However, it differs from the previous one in that:
its additional top layer portion 628, p+ doped and interposed between the additional top layer 620 of n− doped semiconductor material and the anode 606, has box doping in the space charge zone 610, i.e., by lateral junction termination extension (lateral JTE) in the space charge zone 610,
its additional bottom layer portion 630, p+ doped and interposed between the additional bottom layer 622 of n− doped semiconductor material and the anode 614, has box doping in the space charge zone 618, i.e. by lateral junction termination extension (lateral JTE) in the space charge zone 618,
a plurality of portions of an top oxide layer 636 are added to the upper face of the additional top layer 620 of semiconductor material or to that of the additional top layer portions 628, 632 formed of the same semiconductor material, in particular between the anode 606 and the cathode 608, and
a plurality of portions of a bottom oxide layer 638 are added to the lower face of the additional bottom layer 622 of semiconductor material or to that of the additional bottom layer portions 630, 634 formed of the same semiconductor material, particularly between the anode 614 and the cathode 616.

The box doping of the p+ doped additional layer portions 628, 630 provides spatial control of the space charge zones 610, 618 by smoothing the electrostatic fields generated therein, i.e., creating softer field lines so as to avoid field spikes. The boxes are doped according to the same type as the additional layer portion 628 or 630 that they extend. Their more precise configuration and their distribution according to the configurations and arrangements of the other elements of the device are within the reach of the skilled person.

The oxidation of the above-mentioned upper and lower faces, particularly between the anodes and cathodes of the two PIN diodes, makes it possible to neutralize dangling bonds and the resulting electrical disturbances that can be created by manufacturing.

Furthermore, as in the previous embodiments, it is entirely possible to invert the n and p doping of the different layers of semiconductor material of the one-piece device 600.

It should also be noted that in the embodiments of FIGS. 4, 5 and 6, the PIN diodes are formed by placing at least one conductor (in this case the anode) of each conductive layer in contact with a portion of a layer of semiconductor material formed with a doping opposite to that of the substrate layer, i.e., p-doping when the substrate is n-doped or n-doping when the substrate is p-doped.

The one-piece particle detection device 700 shown schematically in cross-section in FIG. 7 has elements 702, 706, 716, 720, 722, 724, 726, 728 and 730 respectively identical to elements 402, 406, 416, 420, 422, 424, 426, 428 and 430 of the one-piece device 400 in FIG. 4.

It further includes top 736 and bottom 738 oxide layer portions like the one-piece device 600 of FIG. 6.

It also has the following additional features:
a hole 740 is hollowed out from the lower face of the oxide/semiconductor layer stack 738, 722, 726, 702, 724, 720, 728 from the oxide layer 738 to a certain depth in the substrate layer 702 opposite the conductor 706,
a hole 742 is hollowed out from the upper face of the oxide/semiconductor layer stack 736, 720, 724, 702, 726, 722, 730 from the oxide layer 736 to a certain depth in the substrate layer 702 opposite the conductor 716,
a conductive layer 714 is disposed at the bottom, sidewall, and flange (i.e., under the oxide layer 738) of the hole 740, and
a conductive layer 708 is disposed on the bottom, sidewall, and flange (i.e., on the oxide layer 736) of the hole 742.

An advantage of this configuration is to thin the part of the one-piece device 700 likely to be crossed by the incident particle beam and thus to improve its transparency, by providing two holes hollowed out in the semiconductor material on either face of the substrate layer 702 around main axes intended to be followed by the particle beam.

By a first appropriate choice of the thicknesses and dimensions of the various components of the one-piece device 700:
the conductive layers 706 and 708 form the anode and cathode, respectively, of a first charge carrier collecting PIN diode, the corresponding space charge zone 710 being formed, like the space charge zone 410 of the one-piece device 400, in the thickness of the additional top layer 720 of semiconductor material between the anode 706 and cathode 708, and
the conductive layers 716 and 714 form the anode and cathode, respectively, of a second charge carrier collecting PIN diode, the corresponding space charge zone 718 being formed, like the space charge zone 418 of the one-piece device 400, in the thickness of the additional bottom layer 722 of semiconductor material between the anode 716 and cathode 714.

By a second appropriate choice of the thicknesses and dimensions of the various components of the one-piece device 700:
the conductive layers 706 and 714 respectively form the anode and cathode of a first charge carrier collecting PIN diode, the corresponding space charge zone 710′ being then offset to the left, contrary to the previous configuration, in the thickness of the additional top layer 720 of semiconductor material between the anode 706 and the cathode 714, and
the conductive layers 716 and 708 respectively form the anode and the cathode of a second charge carrier collecting PIN diode, the corresponding space charge zone 718′ being then offset to the right, contrary to the previous configuration, in the thickness of the additional bottom layer 722 of semiconductor material between the anode 716 and the cathode 708.

According to this second choice of configuration, it is important that the lateral dimensions of the one-piece device 700 are sufficiently small compared to the thickness of the incident beam so that the two space charge zones 710′ and 718′ are passed through by this same beam.

Furthermore, as in the previous embodiments, it is entirely possible to invert the n and p doping of the different semiconductor material layers of the one-piece device 700.

For the sake of simplicity, the preceding embodiments have been presented on the basis of one anode and one cathode per face of the one-piece device, so as to constitute one charge carrier collecting detector per face, whereas it is quite possible to multiply the number of detectors by multiplying the number of anodes and cathodes per face.

The one-piece particle detection device 800 shown schematically in cross-section in FIG. 8 is a non-limiting example of a configuration allowing such a multiplication of detectors. It has a cylindrical cross-section around an axis of symmetry D indicated by mixed dashed line and by the two descending arrows illustrating the path followed by the incident beam.

Like the devices of FIGS. 2 to 7, it comprises several layers (cylindrical in this embodiment) of the same semiconductor material, for example silicon carbide of formula SiC-4H, among which:
a substrate layer 802 of n++ doped semiconductor material with a thickness of 100 to 300 μm,
a top buffer layer 824 of n+ doped semiconductor material epitaxially formed over the substrate layer 802, having a thickness of about 5 μm,
an additional top layer 820 of n− doped semiconductor material epitaxially formed over the top buffer layer 824, having a thickness of 1 to 3 μm,
another ring-shaped additional top layer 832 of semiconductor material formed with n++ doping implanted in the additional top layer 820 of n-doped semiconductor material to a depth having a thickness of about 1 μm,
a top central layer portion 828 formed with p+ doping in the additional top layer 820 of n− doped semiconductor material, within the ring formed by the other additional top layer 832 doped n++,
a bottom buffer layer 826 of n+ doped semiconductor material epitaxially formed underneath the substrate layer 802, having a thickness of about 5 μm,
an additional bottom layer 822 of n− doped semiconductor material epitaxially formed below the bottom buffer layer 826, having a thickness of 1 to 3 μm,
another ring-shaped additional bottom layer 834 of semiconductor material formed with n++ doping implanted in the additional bottom layer 822 of n-doped semiconductor material to a depth having a thickness of about 1 μm, and
a bottom central layer portion 830 formed with p+ doping in the additional bottom layer 822 of n− doped semiconductor material, within the ring formed by the other additional bottom layer 834 doped n++.

With regard to the respective thicknesses of the various aforementioned layers, it should be noted that the scale is not respected in the schematic illustration of FIG. 8, which has no impact on the proper understanding of this embodiment.

On the upper face 804 of the other additional top layer 832 n++ doped and the top central layer portion 828 p+ doped, both formed in the additional top layer 820 of n− doped semiconductor material, are disposed:
a top central layer 806 of conductive metal forming an anode, for example of Ni/Ti/Al/Ni material with a thickness of approximately 100 nm, in the form of a disk with an outer flange arranged above and in contact only with the top central layer portion 828 of p+ doped semi-conductor material,
a top peripheral layer 808 of conductive metal as a cathode, for example of Ti/Ni material with a thickness of about 100 nm, in the form of a ring with an inner flange arranged above and in contact only with the other additional top layer 832 of n++ doped semiconductor material, and
a top oxide layer 836 extending into the ring-shaped interior volume delimited by the respective flanges of the anode 806 and the cathode 808, for example made of SiO2 material and with a thickness of 1 to 3 μm corresponding approximately to the height of the flanges.

Thus, the additional top layer 820 of n− doped semiconductor material actually extends from the top buffer layer 824 to the top oxide layer 836 in the volume left free between the top central layer portion 828 and the top ring-shaped layer 832.

On the lower face 812 of the other additional bottom layer 834 n++ doped and the bottom central layer portion 830 p+ doped, both formed in the additional bottom layer 822 of n− doped semiconductor material, are disposed:
a bottom central layer 814 of conductive metal forming an anode, for example of Ni/Ti/Al/Ni material with a thickness of approximately 100 nm, in the form of a disk with an outer flange arranged below and in contact only with the bottom central layer portion 830 of p+ doped semiconductor material,
a bottom peripheral layer 816 of conductive metal as a cathode, for example of Ti/Ni material with a thickness of about 100 nm, in the form of an inner flanged ring arranged below and in contact only with the other additional bottom layer 834 of n++ doped semiconductor material, and
a lower oxide layer 838 extending into the ring-shaped interior volume delimited by the respective flanges of the anode 814 and cathode 816, for example made of SiO2 material and with a thickness of 1 to 3 μm corresponding approximately to the height of the flanges.

Thus, the additional bottom layer 822 of n− doped semiconductor material actually extends from the bottom buffer layer 826 to the bottom oxide layer 838 in the volume left free between the bottom central layer portion 830 and the bottom ring-shaped layer 834.

As a result, a first top space charge zone 810 is formed below the top central layer portion 828 within the thickness of the layer 820 and about the axis of symmetry D. Similarly, a second bottom space charge zone 818 is formed above the bottom center layer portion 830 within the thickness of the layer 822 and about the axis of symmetry D. The arrangement of the aforementioned successive layers of semiconductor material allows the field lines to be laterally bent and the charge carriers to be collected by means of anode and cathode pairs arranged on the same upper or lower face of the one-piece device 800. In particular, since the space charge zones do not extend in depth beyond layers 820 and 822, the substrate 802 no longer performs more than a mechanical support function.

It is then very easy to realize multiple detectors per face of the one-piece device 800 by insulating multiple conductive angular sectors in the disks 806, 814 and rings 808, 816. For example, by insulating four disk quarters in each of the conductive disks 806, 814 and four corresponding ring quarters in each of the conductive rings 806, 814, four top PIN diodes and four bottom PIN diodes are insulated. With this configuration, it is further possible to design an angular offset about the D-axis of symmetry and passing through of the incident beam between the upper and lower diodes, including a right angle offset as required in some device classes or standards for dual detection.

It should be noted that, alternatively, it is possible to imagine other arrangements for multiplying the number of detectors on each face of a one-piece detection device according to the present invention. In particular, a matrix or other arrangement of a number N of detectors extending laterally on each face makes it possible to envisage several local dual detections in the section of the incident particle beam.

It appears clearly that a one-piece detection device such as one of those described above allows for a reduction in size and cost while improving the transparency of the dual detection that is increasingly required for safety reasons in particle emission systems.

Another advantage appears more clearly in the embodiment of FIG. 8 and concerns the current-to-voltage conversion circuit (not illustrated) downstream of the detectors. Indeed, the structure proposed in this figure has the advantage of having for each diode constituted on the surface of the one-piece device 800 its own anode but especially its own cathode. The polarization on each of the cathodes that the adaptation of the conversion circuit to the detectors requires is made possible thanks to this structure which becomes essential because it makes it possible to meet two requirements: to have several signal outputs on each of the cathodes with a very low polarization of the detector. Another solution could be to invert the doping zones in the semiconductor material of the one-piece device 800. This is quite possible, but it is more expensive because the market for SiC material is mainly dedicated to power components and, for technical reasons, SiC wafers are generally not developed with positive doping.

It should further be noted that the invention is not limited to the various embodiments described above.

In particular, all the detectors considered in the above-described embodiments are Schottky or PIN diodes. However, other semiconductor material detectors can be considered, such as transistors (for example CMOS, JFET or bipolar).

Furthermore, there may be an asymmetry of detectors arranged on either face of the substrate of a one-piece detecting device according to the present invention, such as different diodes, diodes and transistors, etc.

It will be more generally apparent to the person skilled in the art that various amendments can be made to the above-described embodiments in light of the teaching just disclosed. In the above detailed presentation of the invention, the terms used should not be construed as limiting the invention to the embodiments set forth in the present description, but should be construed to include all equivalents the anticipation of which is within the reach of the person skilled in the art by applying their general knowledge to the implementation of the teaching just disclosed to them.

1. A one-piece device for detecting particles with semiconductor material comprising:
a substrate layer formed in the semiconductor material,
at least one additional layer formed in at least one of the semiconductor material in at least one conductive material disposed on a first face of the substrate layer so as to form at least a first detector comprising:
a first electronic space charge zone through which a first axis of the detection device to be followed by a particle beam passes, and
first collector means for collecting charge carriers produced by the particle beam passing through the first space charge zone,
wherein the device further comprises at least one other additional layer formed in at least one of the semiconductor material and in at least one conductive material disposed on a second face of the substrate layer, opposite to the first face, so as to form at least a second detector independent of the first detector from the substrate layer and comprising:
a second electronic space charge zone, through which a second axis of the detection device parallel to the first axis and to be followed by the particle beam passes, and
second collector means for collecting charge carriers produced by the particle beam passing through the second space charge zone, the second collector means being electrically insulated from the first collector means to ensure independence of the first and second detectors.

2. The one-piece particle detection device according to claim 1, wherein:
the at least one additional layer comprises one of:
a first additional layer formed in the at least one conductive material disposed directly on the first face of the substrate layer, and
a second additional layer formed in the semiconductor material by epitaxy from the substrate layer, the first additional layer formed in the at least one conductive material being disposed indirectly on the first face of the substrate layer via the second additional layer formed in the semiconductor material,
so as to form an anode and a cathode of a first Schottky diode, and
the at least one other additional layer comprises one of:
a third additional layer formed in the at least one conductive material disposed directly on the second face of the substrate layer, and
a fourth additional layer formed in the semiconductor material by epitaxy from the substrate layer, the third additional layer formed in the at least one conductive material being disposed indirectly on the second face of the substrate layer via the fourth additional layer formed in the semiconductor material,
so as to form an anode and a cathode of a second Schottky diode.

3. The one-piece particle detection device according to claim 1, wherein:
the at least one additional layer comprises at least one first additional layer portion formed in the semiconductor material with opposite doping type to that of the substrate layer and a first additional layer formed in said at least one conductive material of which at least one conductor is in contact with the at least one first additional layer portion formed in the semiconductor material, so as to form a first PIN diode, and
the at least one other additional layer comprises at least one second additional layer portion formed in the semiconductor material with an opposite doping type to that of the substrate layer and a second additional layer formed in the at least one conductive material of which at least one conductor is in contact with the at least one second additional layer portion formed in the semiconductor material, so as to form a second PIN diode.

4. The one-piece particle detection device according to claim 1, comprising two buffer layers respectively formed by epitaxy from the first and second faces of the substrate layer.

5. The one-piece particle detection device according to claim 11, comprising two holes hollowed out in the semiconductor material on either face of the substrate layer about the first and second parallel axes to be followed by the particle beam respectively.

6. The one-piece particle detection device according to claim 1, wherein the substrate layer is n++ doped.

7. The one-piece particle detection device according to claim 1, wherein a plurality of first detectors and a plurality of second detectors are formed.

8. The one-piece particle detection device according to claim 1, wherein the at least one second detector is formed to have diodes angularly offset at right angles to corresponding diodes of the at least one first detector about a common direction of the first and second parallel axes to be followed by the particle beam.

9. The one-piece particle detection device according to claim 1, wherein the substrate layer common to the detectors is formed in the semiconductor material.

10. The one-piece particle detection device according to claim 1, wherein the first and second parallel axes are coincident.
